(19) United States
(12) Patent Application Publication
(10) Pub. No.: US 2012/0086044 A1
(43) Pub. Date: Apr. 12, 2012

(54) LIGHT EMITTING DEVICE AND METHOD OF PRODUCING LIGHT EMITTING DEVICE

(75) Inventors: Masahiko HATA, Tsuchiura-shi (JP); Hiroyuki SAZAWA, Tsukuba-shi (JP); Sadanori YAMANAKA, Chiba-shi (JP)

(73) Assignee: SUMITOMO CHEMICAL CO., LTD., Tokyo (JP)

(21) Appl. No.: 13/327,313

(22) Filed: Dec. 15, 2011

Related U.S. Application Data
(63) Continuation-in-part of application No. PCT/JP2010/004050, filed on Jun. 17, 2010.

(30) Foreign Application Priority Data
Jun. 19, 2009 (JP) 2009-146760

(51) Int. Cl. H01L 33/30

(52) U.S. Cl. 257/103; 438/23; 257/E33.023

(57) ABSTRACT

There is provided a light emitting device that includes a base wafer that contains silicon, a plurality of seed bodies provided in contact with the base wafer, and a plurality of Group 3-5 compound semiconductors that are each lattice-matched or pseudo-lattice-matched to corresponding seed bodies. In the device, a light emitting element that emits light in response to current supplied thereto is formed in at least one of the plurality of the Group 3-5 compound semiconductors, and a current limiting element that limits the current supplied to the light emitting element is formed in at least one of the plurality of the Group 3-5 compound semiconductors other than the Group 3-5 compound semiconductor in which the light emitting element is formed.

The contents of the following Japanese patent application and PCT patent application are incorporated herein by reference:
JP2009-146760 filed on Jun. 19, 2009, and
PCT/JP2010/004050 filed on Jun. 17, 2010.

### TECHNICAL FIELD

The present invention relates to a light emitting device and a method of producing a light emitting device.

### BACKGROUND ART

LED array chips in which a plurality of light emitting diodes (LEDs) are arranged, and LED driving circuits which drive the LED array chips have been known (for example, see Patent Document 1). The above-stated Patent Document 1 is JP-5-16423A.

### SUMMARY OF THE INVENTION

### Problem to be Solved by the Invention

LED arrays are used for, for example, printer heads. An LED driving circuit driving an LED array is typically provided in the form of an IC chip which is formed on a semiconductor wafer different from a wafer on which the LED is provided. As more requests for downsizing of high image-quality and high resolution printers arise, there are increasing demands for smaller LED array chips and LED driving circuits.

As a material for LEDs, for instance, a Group 3-5 compound semiconductor with a high luminance efficiency such as GaAs is used. Therefore, it is possible to minimize the size of an LED array chip and LED driving circuit by forming the LED array and the LED driving circuit on the same GaAs wafer. However, the heat conductivity of GaAs is not so high that heat generated from the LED driving circuit cannot be sufficiently dissipated. For this reason, it is difficult to suppress temperature rise in the LED driving circuit and so forth when the LED driving circuit is formed on the GaAs wafer. When the temperature rises in the LED driving circuit, a printer head can be expanded due to heat, and consequently the quality of the image printed by the printer head can be deteriorated.

### Means for Solving Problem

For a solution to the above-mentioned problems, according to the first aspect related to the present invention, provided is one exemplary light emitting device. The light emitting device includes a base wafer that contains silicon, a plurality of seed bodies provided in contact with the base wafer, and a plurality of Group 3-5 compound semiconductors that are each lattice-matched or pseudo-lattice-matched to corresponding seed bodies. A light emitting element that emits light in response to current supplied thereto is formed in at least one of the plurality of the Group 3-5 compound semiconductors, and a current limiting element that limits the current to be supplied to the light emitting element is formed in at least one of the plurality of the Group 3-5 compound semiconductors other than the Group 3-5 compound semiconductor in which the light emitting element is formed.

The light emitting device can further include an inhibitor that inhibits crystal growth and in which a plurality of apertures exposing at least a part of the base wafer are provided, the inhibitor being formed directly or indirectly on the base wafer, and the plurality of the seed bodies are provided in the plurality of the apertures. The plurality of the seed bodies have a composition Cₓ₁Si_{y1}Ge_{z1}Sn_{1-x1-y1-z1} (0≦x1<1, 0≦y1≦1, 0≦z1≦1, and 0<x1+y1+z1≦1).

The light emitting device can further include an interface region provided inside the base wafer in contact with an interface between the base wafer and the seed body, the interface region having a composition Cₓ₂Si_{y2}Ge_{z2}Sn_{1-x2-y2-z2} (0≦x2<1, 0<y2≦1, 0≦z2≦1, and 0<x2+y2+z2≦1). Here, x1 for the seed body and x2 for the region satisfy the relation x1>x2, y1 for the seed body and y2 for the region satisfy the relation y1<y2, z1 for the seed body and z2 for the region satisfy the relation z1>z2, and 1−x1−y1−z1 for the seed body and 1−x2−y2−z2 for the region satisfy the relation 1−x1−y1−z1>1−x2−y2−z2.

The base wafer has a well region that is in contact with the plurality of the seed bodies, and the light emitting element is electrically coupled to the current limiting element via the plurality of the seed bodies and the well region. The current limiting element can be a resistor element that limits current to be supplied to the light emitting element. The resistor element includes a carrier trap that traps a carrier.

The current limiting element is a thyristor that switches current to be supplied to the light emitting element. The thyristor includes a multilayered structure in which a P-type semiconductor, an N-type semiconductor, a P-type semiconductor, and an N-type semiconductor are layered in the stated order. The silicon has the same conductivity type as the conductivity type of the plurality of the Group 3-5 compound semiconductors that are in contact with the plurality of the seed bodies. The light emitting further includes a silicon element formed in a region of the base wafer, the region contains the silicon, and the silicon element supplies current to the light emitting element. The plurality of apertures can be arranged at regular intervals in the inhibitor.

According to the second aspect related to the present invention, provided is a method of producing a light emitting device. The method includes forming a plurality of seed bodies in contact with a base wafer whose surface is made of silicon, forming a plurality of Group 3-5 compound semiconductors each lattice-matching or pseudo-lattice-matching a corresponding seed body by crystal growth, forming, in at least one of the plurality of the Group 3-5 compound semiconductors, a light emitting element that emits light in response to current to be supplied thereto, and forming, in at least one of the plurality of the Group 3-5 compound semiconductors other than the Group 3-5 compound semiconductor in which the light emitting element is formed, a current limiting element that limits current to be supplied to the light emitting element.

The method can further include heating the plurality of the seed bodies after forming the plurality of seed bodies and before forming the plurality of the Group 3-5 compound semiconductors by crystal growth. The method of producing a light emitting device further includes forming, directly or indirectly on the base wafer, an inhibitor that inhibits crystal growth and that has a plurality of apertures in which at least a part of the base wafer is exposed. In forming the plurality of the seed bodies, the seed bodies are provided in the apertures.

### BRIEF DESCRIPTION OF THE DRAWINGS

FIG. 1 shows an example of a cross section of a light emitting device 100.

FIG. 2 illustrates a cross section of the light emitting device 100 during a production process.

FIG. 3 illustrates another cross section of the light emitting device 100 during the production process.

FIG. 4 illustrates another cross section of the light emitting device 100 during the production process.

FIG. 5 shows an example of a cross section of a light emitting device 200.

FIG. 6 illustrates a cross section of the light emitting device 200 during a production process.

FIG. 7 illustrates another cross section of the light emitting device 200 during the production process.

FIG. 8A shows an example of a cross section of a light emitting device 300.

FIG. 8B shows another example of a cross section of the light emitting device 300.

FIG. 9 illustrates a cross section of the light emitting device 300 during a production process.

FIG. 10 illustrates another cross section of the light emitting device 300 during the production process.

FIG. 11 illustrates another cross section of the light emitting device 300 during the production process.

FIG. 12 shows an example of a cross section of a light emitting device 400.

FIG. 13 shows an example of a cross section of a light emitting device 500.

FIG. 14 shows an example of a cross section of a light emitting device 600.

FIG. 15 illustrates a cross section of the light emitting device 600 during a production process.

FIG. 16 illustrates another cross section of the light emitting device 600 during the production process.

FIG. 17 illustrates another cross section of the light emitting device 600 during the production process.

FIG. 18 illustrates another cross section of the light emitting device 600 during the production process.

FIG. 19 illustrates another cross section of the light emitting device 600 during the production process.

FIG. 20 illustrates another cross section of the light emitting device 600 during the production process.

FIG. 21 illustrates another cross section of the light emitting device 600 during the production process.

FIG. 22 shows an example of a cross section of a light emitting device 700.

### MODE FOR CARRYING OUT THE INVENTION

FIG. 1 shows an example of a cross section of a light emitting device 100 according to an embodiment. The light emitting device 100 includes a base wafer 102, an inhibitor 106, a seed body 112, a light emitting diode 120, an electrode 132 and an electrode 134.

A surface of the base wafer 102 is made of silicon. Here, “the surface is made of silicon” means that the surface of the wafer has at least a region where is composed of silicon element. For instance, the whole of the base wafer 102 can be made of silicon like a Si wafer, or the base wafer 102 can have a structure such as silicon-on-insulator (SOI) in which a silicon layer is formed on an insulating layer. Note that the base wafer 102 can have a silicon layer which is grown on a sapphire or glass substrate that has a different composition from silicon. The silicon forming the base wafer 102 can include an impurity. Moreover, the base wafer 102 can have a thin oxide silicon layer such as a native oxide layer or a thin nitride silicon layer formed on the silicon layer at the wafer surface.

The base wafer 102 is a single wafer. The base wafer 102 can include a high-resistance silicon portion. For example, the base wafer 102 illustrated in FIG. 1 is a high-resistance Si wafer. A plurality of seed bodies 112 are formed on the base wafer 102. A light emitting diode 120 can be formed on each seed body 112. Here, “high resistance” refers to a resistance of 100 Ω·cm or above.

The inhibitor 106 inhibits crystal growth. For example, when crystal of semiconductor is grown by the epitaxial growth method, the epitaxial growth of the semiconductor crystal is inhibited on the surface of the inhibitor 106. Consequently, the crystal of the semiconductor is selectively grown in an aperture 108 by the epitaxial growth method.

The inhibitor 106 is formed on the base wafer 102. A plurality of apertures 108 in which at least a part of the base wafer 102 is exposed are formed in the inhibitor 106. For example, the plurality of apertures 108 are regularly arranged. The seed body 112 can be formed in at least one of the plurality of apertures 108.

The inhibitor 106 is, for example, a silicon oxide layer, a silicon nitride layer, a silicon oxynitride layer, or stacked layers including these layers. The thickness of the inhibitor 106 is, for example, 0.05 μm to 5 μm. The inhibitor 106 is formed by, for example, a thermal oxidation method, a CVD method or the like.

The seed body 112 is formed on the base wafer 102. More specifically, each of a plurality of the seed bodies 112 is formed in contact with the base wafer 102 respectively inside the aperture 108 in the inhibitor 106. The plurality of seed bodies 112 are lattice-matched or pseudo-lattice-matched to the base wafer 102.

In this specification, “pseudo-lattice matching” means the state which is not a perfect lattice matching but in which a difference in the lattice constant between two contacting semiconductors is small and the two contacting semiconductors can be disposed on top of each other to the extent where defects due to lattice mismatch are less represented. At this state, the crystal lattice of each semiconductor deforms within its elastic deformable range, and the difference in the lattice constant can be absorbed. For example, a layered structure of Ge and GaAs or Ge and InGaP within a limit thickness for lattice relaxation is referred to as the pseudo-lattice matching.

The seed body 112 has a composition Cₓ₁Si_{y1}Ge_{z1}Sn_{1-x1-y1-z1} (0≦x1<1, 0≦y1≦1, 0≦z1≦1, and 0<x1+y1+z1≦1). For instance, the seed body 112 is a Ge crystal, a SiGe crystal or a GeSn crystal. The seed body 112 can have a multi-layered structure that includes semiconductor layers having different compositions, doping concentrations and thicknesses.

The seed body 112 can include an interface region having a composition Cₓ₂Si_{y2}Ge_{z2}Sn_{1-x2-y2-z2} (0≦x2<1, 0≦y2≦1, 0≦z2≦1, and 0<x2+y2+z2≦1) and provided in the base wafer 102 so as to be in contact with the interface between the base wafer 102 and the seed body 112. Here, x1 for the seed body 112 and x2 for the above-mentioned interface region satisfy the relation x1>x2, y1 for the seed body 112 and y2 for the above-mentioned interface region satisfy the relation y1<y2, z1 for the seed body 112 and z2 for the above-mentioned interface region satisfy the relation z1>z2, and 1−x1−y1−z1 for the seed body 112 and 1−x2−y2−z2 for the interface region satisfy the relation 1−x1−y1−z1>1−x2−y2−z2.

The seed body 112 is a semiconductor that provides a seed plane appropriate for crystal growth for the light emitting diode 120 formed on the seed body. The seed body 112 can be a semiconductor that prevents an adverse effect of the impurity existing on a surface of the base wafer 102 to the crystallinity of the light emitting diode 120.

The seed body 112 is formed by, for example, an epitaxial growth method. The epitaxial growth method encompasses a chemical vapor deposition method (also referred to as a CVD method), a metal organic chemical vapor deposition method (also referred to as a MOCVD method), a molecular beam epitaxy method (also referred to as a MBE method) and an atomic layer deposition method (also referred to as an ALD method). The seed bodies 112 arranged in an island pattern can be formed by forming a film of the seed body 112 on the base wafer 102, and then patterning the seed body 112 by a photolithography method such as etching. In this case, the seed bodies 112 arranged in the island pattern are separated from each other.

The seed body 112 is preferably heated. A lattice defect such as dislocation could occur inside the seed body 112 due to the difference in the lattice constant between the base wafer 102 and the seed body 112. This lattice defect travels inside the seed body 112, for example, when the seed body 112 is heated. The lattice defect travels inside the seed body 112 and then is captured by a gettering sink and so forth at the interface of the seed body 112 or inside the seed body 112. Therefore, it is possible to reduce defects in the seed body 112 by heating the seed body 112, resulting in improvement in the crystallinity of the seed body 112. The seed body 112 can be formed by heating amorphous or polycrystalline Cx₁Si_{y1}Ge_{z1}Sn_{1-x1-y1-z1} (0≦x1<1, 0≦y1≦1, 0≦z1≦1, and 0<x1+y1+z1≦1).

The light emitting diode 120 is formed in contact with the seed body 112. A plurality of the light emitting diodes 120 are formed such that each light emitting diode 120 is in contact with the corresponding seed body 112. The plurality of light emitting diodes 120 are regularly arranged. The light emitting device 100 can include other semiconductor layers provided between the light emitting diode 120 and the seed body 112. The light emitting diode 120 is lattice-matched or pseudo-lattice-matched to the seed body 112.

The light emitting diode 120 is, for example, an electronic element having two terminals that have a rectification capability or a semiconductor element having two terminals of a cathode and anode. For example, the light emitting diode 120 has an N-type semiconductor 122 and a P-type semiconductor 124. The light emitting diode 120 emits light according to a current supplied thereto. More specifically, the light emitting diode 120 emits light when a current flows from the P-type semiconductor 124 to the N-type semiconductor 122 when a forward bias voltage which is higher than the N-type semiconductor 122 is applied to the P-type semiconductor 124.

The N-type semiconductor 122 and the P-type semiconductor 124 are, for example, a Group 3-5 compound semiconductor. An example of the Group 3-5 compound semiconductor includes GaP, GaAs, GaAsP, AlGaAs, InGaP, InGaAsP, AlInGaP, GaN, InGaN, AlGaN, AlInGaN and InP. The light emitting diode 120 can include a PN junction formed between the Group 3-5 compound semiconductor and other compound semiconductor.

The N-type semiconductor 122 and the P-type semiconductor 124 can respectively have a multi-layered structure that includes semiconductor layers having different compositions, doping concentrations and thicknesses. A PN junction is formed at the interface between the N-type semiconductor 122 and the P-type semiconductor 124. When a forward bias is applied to the light emitting diode 120, an electron from the N-type semiconductor and an hole from the P-type semiconductor move toward a depletion layer near the PN junction, and the PN junction serves as a light emitting section that emits light when the electron and the hole are recombined therein. The light emitting diode 120 is formed by, for example, an epitaxial growth method. An example of the epitaxial growth method includes CVD, MOCVD, MBE and ALD methods.

The electrode 132 is formed in contact with the P-type semiconductor 124. The electrode 132 serves as an anode electrode of the light emitting diode 120. The electrode 134 is formed in contact with the N-type semiconductor 122. The electrode 134 serves as a cathode electrode of the light emitting diode. The electrode 132 and the electrode 134 connect the light emitting diode 120 to an external circuit. The electrode 132 and the electrode 134 are formed of an electrically conductive material. A material for the electrode 132 and the electrode 134 is, for example, metal.

When the P-type semiconductor 124 is a GaAs based semiconductor, a material for the electrode 132 is, for example, AuZn/Au, which are provided in the stated order from the side of the P-type semiconductor 124. When the P-type semiconductor 124 is a GaN based semiconductor, a material for the electrode 132 is, for example, Ni/Au, which are provided in the stated order from the side of the P-type semiconductor 124. When the N-type semiconductor 122 is a GaAs based semiconductor, a material for the electrode 134 is, for example, AuGe/Ni/Au, which are provided in the stated order from the side of the N-type semiconductor 122. When the N-type semiconductor 122 is a GaN based semiconductor, a material for the electrode 134 is, for example, Ti/Au, which are provided in the stated order from the side of the N-type semiconductor 122. The electrode 132 and the electrode 134 are formed by a sputtering method, a vacuum deposition method or the like.

Referring to FIG. 1, the light emitting diode 120 is formed by depositing the N-type semiconductor 122 and the P-type semiconductor 124 sequentially from the side of the base wafer 102. The light emitting diode 120 can also be formed by depositing the P-type semiconductor and the N-type semiconductor sequentially from the side of the base wafer 102.

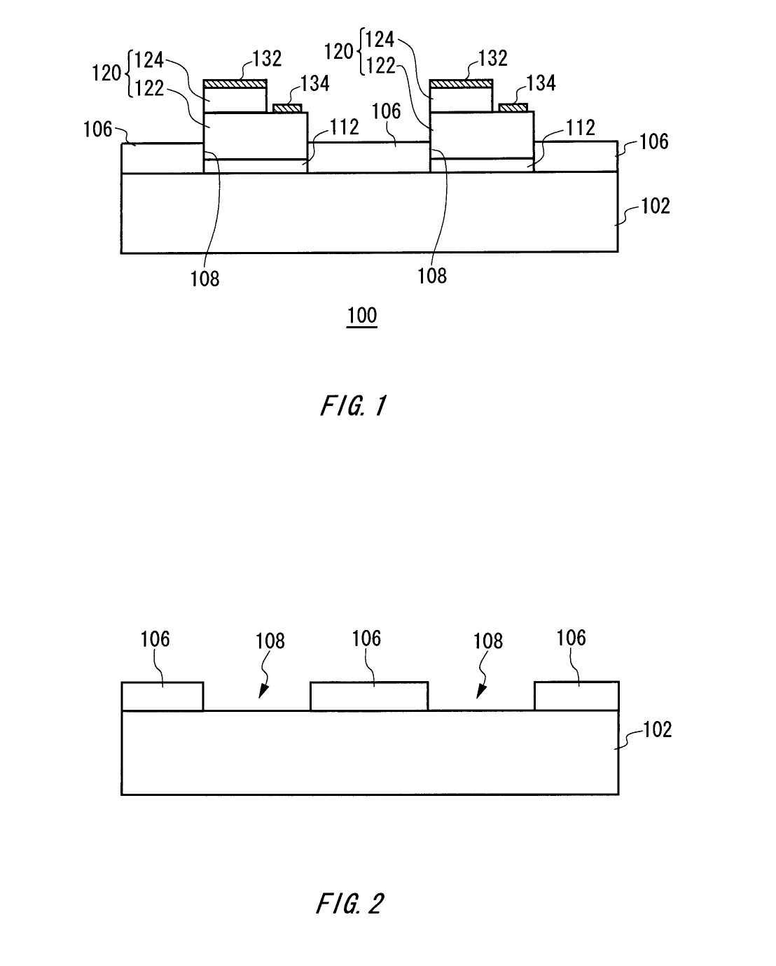

FIGS. 2 through 4 illustrate cross sections of the light emitting device 100 during a production process. A method of producing the light emitting device 100 will be now described with reference to the accompanying drawings. The method of producing the light emitting device 100 includes forming an inhibitor, forming a seed body, and forming the light emitting diode 120. Heating of the seed body can be further performed between the seed body formation and the formation of the light emitting diode 120.

During the formation of the inhibitor, the inhibitor 106 that inhibits crystal growth is formed on the base wafer 102, and the aperture 108 that exposes at least a part of the base wafer 102 is formed in the inhibitor 106. For example, a silicon oxide film which serves as the inhibitor 106 is formed on the whole surface of the base wafer 102 by a thermal oxidation method as shown in FIG. 2, and then a plurality of the apertures 108 that extend to the base wafer 102 can be formed in the silicon oxide film by a photolithography method such as etching.

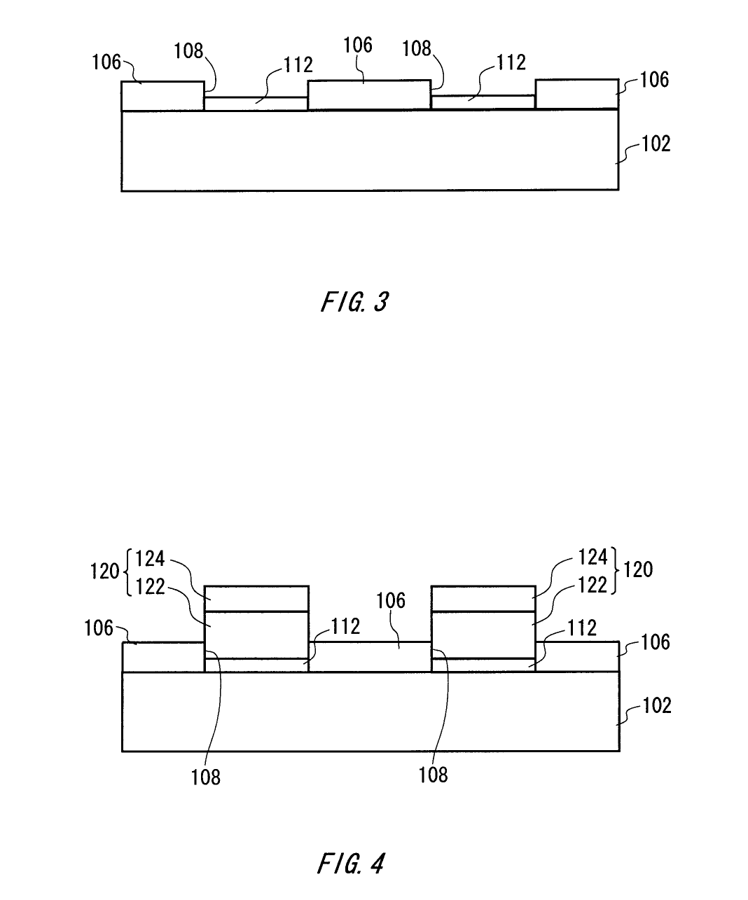

During the formation of the seed body, the seed body 102 is formed in the aperture 108 such that it is in contact with the base wafer 102 at the bottom of the aperture 108. For example, as illustrated in FIG. 3, the seed body 112 is formed in the aperture 108 so as to be in contact with the base wafer 102 by a selective epitaxial method. The epitaxial growth method includes CVD, MOCVD, MBE and ALD methods. The seed body 112 is formed by epitaxially growing a Ge crystal, a SiGe crystal or a GeSn crystal by a CVD method. When the inhibitor 106 that has the plurality of apertures 108 is formed, the seed body 112 is formed respectively in each of the plurality of apertures 108.

During the heating of the seed body, it is possible to reduce lattice defects such as dislocation generated inside the seed body 112 due to a difference in the lattice constant between the base wafer 102 and the seed body 112, by heating the seed body 112, and therefore the crystallinity of the seed body 112 can be improved. When the seed body 112 is heating, heating can be performed in more than one step. For example, the heating includes a high-temperature heating which is performed at a temperature that does not reach to the melting point of the seed body 112, and a low-temperature heating which is performed at a temperature that is lower than the temperature of the high-temperature heating. These two heating steps can be repeated more than one time.

When the seed body 112 contains SiₓGe₁₋ₓ (0≦x<1), the temperature and time duration of the high-temperature heating are, for example, no less than 850° C. and no more than 900° C. and 2 to 10 minutes respectively. The temperature and time duration of the low-temperature heating are, for example, no less than 650° C. and no more than 780° C. and 2 to 10 minutes respectively. These two heating steps can be repeated, for example, 10 times.

During the formation of the light emitting diode 120, the N-type semiconductor 122 and the P-type semiconductor 124 that are in contact with the heated seed body 112 and that are lattice-matched or pseudo-lattice-matched to the seed body 112 are formed. For example, as illustrated in FIG. 4, selective epitaxial growth is performed to grow the N-type semiconductor 122 and the P-type semiconductor 124 sequentially on the seed body 112. When a plurality of the seed bodies 112 are formed, the N-type semiconductor 122 and the P-type semiconductor 124 can be formed on each of the plurality of seed bodies 112.

The epitaxial growth method includes CVD, MOCVD, MBE and ALD methods. The light emitting diode 120 is formed by, for example, epitaxially growing a Group 3-5 compound semiconductor such as GaAs, AlGaAs, InGaP, GaN or the like using a MOCVD method. The epitaxial growth is performed in the following way. After the atmosphere inside an MOCVD reactor is sufficiently replaced by high-purity hydrogen, heating of the base wafer 102 having the seed body 112 is started. A wafer temperature at the time of crystal growth can be, for example, any temperature between 450° C. to 800° C. When the temperature of the base wafer 102 is settled to an adequate temperature, an arsenic source or a phosphorus source is introduced into the reactor. Subsequently, a gallium source, an aluminum source or an indium source is introduced into the reactor to epitaxially grow the N-type semiconductor 122 and the P-type semiconductor 124 sequentially.

As the Group 3 element source, it is possible to use trimethyl gallium (TMG), trimethyl alminium (TMA), trimethyl indium (TMI) or the like. As a Group 5 element source gas, it is possible to use arsine (AsH₃), tertiary butyl arsine ((CH₃)₃CAsH₂), phosphine (PH₃), tertiary butyl phosphine ((CH₃)₃CPH₂), ammonia (NH₃) or the like. As a carrier gas for the source, high-purity hydrogen can be used. The N-type impurity element includes Si, S, Se and Te. The P-type impurity element includes C, Ge, Be, Mg, Zn and Cd.

Conditions for the epitaxial growth are, for example, a pressure inside the reactor of 0.1 atm, a growth temperature of 650° C. and a growth rate of 0.1 μm/hr to 3 μm/hr. The epitaxial growth can also be performed in the following way. GaAs is firstly epitaxially grown to about 30 nm thick under the conditions of a pressure inside the reactor of 0.1 atm, a growth temperature of 550° C. and a growth rate of 0.1 μm/hr to 1 μm/hr, and the growth is then temporally suspended. The temperature is raised to 650° C. while the arsenic source atmosphere is retained to realize the epitaxial growth conditions of a pressure inside the reactor of 0.1 atm, a growth temperature of 650° C. and a growth rate of 0.1 μm/hr to 3 μm/hr.

Subsequently, the electrode 132 and the electrode 134 are formed and the light emitting device 100 is completed. These electrodes can be formed in the following way. A resist pattern that has apertures at positions where the electrodes are to be formed is formed. After that, metal that is to be the electrodes is deposited by, for example, sputtering. When the light emitting diode 120 is made of a GaAs based semiconductor, AuZn/Au are formed as the electrode 132 in the stated order from the side of the base wafer 102, and AuGe/Ni/Au are formed as the electrode 134 in the stated order from the side of the base wafer 102. When the light emitting diode 120 is made of a GaN based semiconductor, Ni/Au are formed as the electrode 132 in the stated order from the side of the base wafer 102, and Ti/Au are formed as the electrode 134 in the stated order from the side of the base wafer 102. The resist is lifted off at the end of the process, and the electrode 132 and the electrode 134 are completed.

FIG. 5 shows an example of a cross section of a light emitting device 200 according to another embodiment. The light emitting device 200 includes the base wafer 102, the inhibitor 106, the seed body 112, a thyristor 220, a gate electrode 232, a cathode electrode 234 and an anode electrode 236. The base wafer 102, the inhibitor 106 and the seed body 112 have been described above with reference to FIG. 1 and therefore explanations thereof will be hereunder omitted.

Here, the thyristor 220 is a switching element that has more than two PN junctions and that is capable of switching ON and OFF, or an element that has a PNPN structure to perform a switching operation. A multilayer structure represented by P-type semiconductor/N-type semiconductor/P-type semiconductor/N-type semiconductor refers to a multilayer structure in which a P-type semiconductor, an N-type semiconductor, a P-type semiconductor, and an N-type semiconductor are formed on top of each other in the stated order, or a multilayer structure in which an N-type semiconductor, a P-type semiconductor, an N-type semiconductor, and a P-type semiconductor are formed on top of each other in the stated order. For example, referring to FIG. 5, the thyristor 220 is formed by forming a multilayer structure including a P-type semiconductor 222, an N-type semiconductor 224, a P-type semiconductor 226, and an N-type semiconductor 228 sequentially stacked in the stated order from the side of the base wafer 102. The thyristor 220 can also be formed by forming a multilayer including an N-type semiconductor, a P-type semiconductor, an N-type semiconductor, and a P-type semiconductor sequentially stacked in the stated order from the side of the base wafer 102.

The thyristor 220 is a current limiting element that limits current supplied to the light emitting element by switching between a conduction state and a non-conduction state in response to a control signal input to the gate electrode 232. The thyristor 220 is formed in contact with the seed body 112. In the thyristor 220, for example, the P-type semiconductor 222, which is the bottom layer of the thyristor 220, is formed in contact with the seed body 112, and then the N-type semiconductor 224, the P-type semiconductor 226 and the N-type semiconductor 228 are sequentially formed.

A plurality of the thyristors 220 can be formed such that each of the thyristor is in contact with a respective one of the seed bodies 112. The plurality of thyristors 220 can be regularly arranged. The thyristor 220 can be formed on the seed body 112 with other semiconductor layer interposed therebetween. The thyristor 220 is lattice-matched or pseudo-lattice-matched to the seed body 112.

The thyristor 220 can contain a Group 3-5 compound semiconductor. An example of the Group 3-5 compound semiconductor includes GaP, GaAs, GaAsP, AlGaAs, InGaP, InGaAsP, AlInGaP, GaN, InGaN, and InP.

The P-type semiconductor 222, the N-type semiconductor 224, the P-type semiconductor 226, and the N-type semiconductor 228 can respectively have a multi-layered structure that includes semiconductor layers having different compositions, doping concentrations and thicknesses. The thyristor 220 is formed by, for example, an epitaxial growth method. An example of the epitaxial growth method includes CVD, MOCVD, MBE and ALD methods.

The gate electrode 232 is formed in contact with the P-type semiconductor 226 that serves as a gate of the thyristor 220. The gate electrode 232 connects the P-type semiconductor 226 to an external circuit, and receives a gate control signal input thereto. The gate electrode 232 is formed of an electrically conductive material. A material for the gate electrode 232 is, for example, metal. When the thyristor 220 includes a GaAs based semiconductor, a material for the gate electrode 232 is, for example, AuZn/Au, which are provided in the stated order from the side of the semiconductor. When the thyristor 220 includes a GaN based semiconductor, a material for the gate electrode 232 is, for example, Ni/Au, which are provided in the stated order from the side of the semiconductor. The gate electrode 232 is formed by a sputtering method, a vacuum deposition method or the like.

The cathode electrode 234 is formed in contact with the N-type semiconductor 228. The cathode electrode 234 connects the thyristor 220 to an external circuit to which a driving current is to be supplied. The cathode electrode 234 outputs the driving signal to, for example, an external circuit. The cathode electrode 234 is formed of an electrically conductive material. The cathode electrode 234 is formed of, for example, metal. When the thyristor 220 includes a GaAs based semiconductor, a material for the cathode electrode 234 is, for example, AuGe/Ni/Au, which are provided in the stated order from the side of the semiconductor. When the thyristor 220 includes a GaN based semiconductor, a material for the cathode electrode 234 is, for example, Ti/Au, which are provided in the stated order from the side of the semiconductor. The cathode electrode 234 is formed by a sputtering method, a vacuum deposition method or the like.

The anode electrode 236 is formed in contact with the P-type semiconductor 222. The anode electrode 236, for example, connects the thyristor 220 to a power source. The anode electrode 236 receives, from the power source, the driving current which the cathode electrode 234 should supply to an external circuit. The anode electrode 236 is formed of an electrically conductive material. The anode electrode 236 is formed of, for example, metal. When the thyristor 220 includes a GaAs based semiconductor, a material for the anode electrode 236 is, for example, AuZn/Au, which are provided in the stated order from the side of the semiconductor. When the thyristor 220 includes a GaN based semiconductor, a material for the anode electrode 236 is, for example, Ni/Au, which are provided in the stated order from the side of the semiconductor. The anode electrode 236 is formed by a sputtering method, a vacuum deposition method or the like.

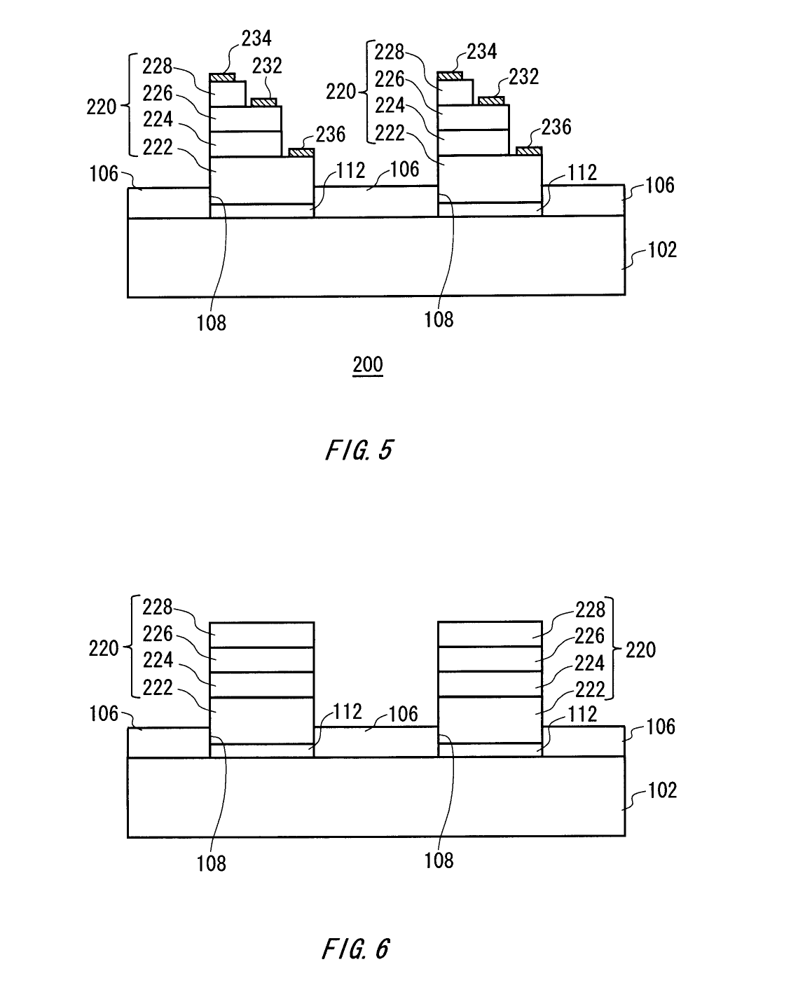

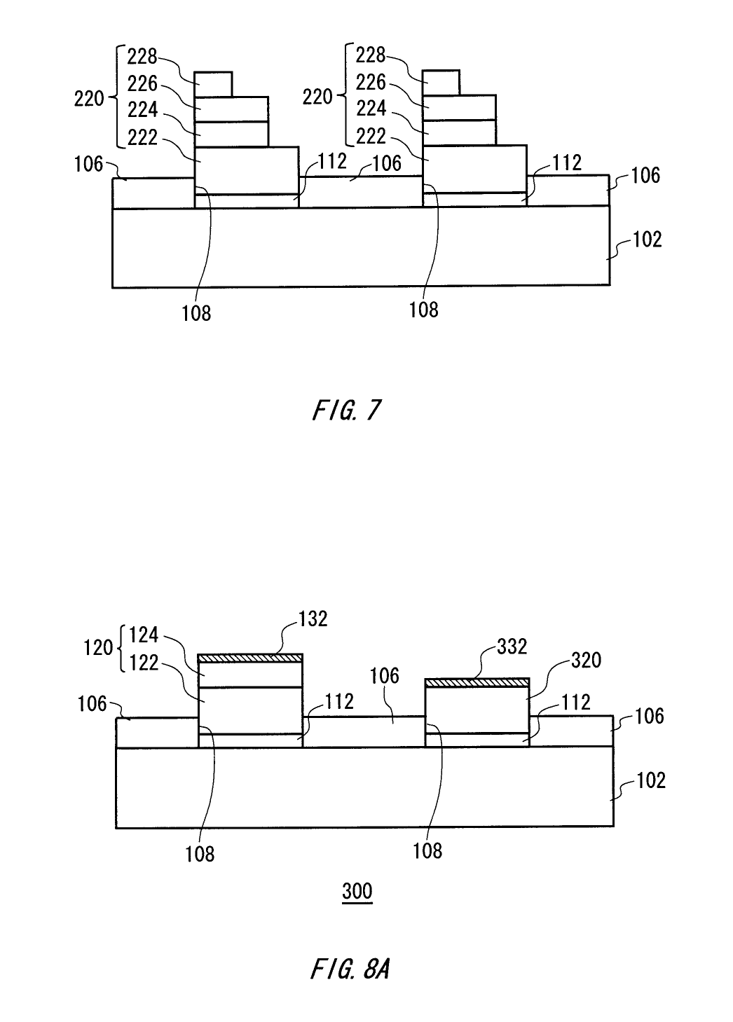

FIG. 6 and FIG. 7 illustrate cross sections of the light emitting device 200 during a production process. A method of producing the light emitting device 200 will be now described with reference to the accompanying drawings. The method of producing the light emitting device 200 includes forming an inhibitor, forming a seed body, and forming the thyristor 220. Heating of the seed body can be further performed between the seed body formation and the formation of the thyristor 220. In the same manner as the light emitting device 100, the semiconductor wafer shown in FIG. 3 can be obtained through the process of forming the seed body and the process of heating the seed body.

Referring to FIG. 6, during the formation of the light emitting diode 220, the P-type semiconductor 222, the N-type semiconductor 224, the P-type semiconductor 226, and the N-type semiconductor 228 that are in contact with the heated seed body 112 and that are lattice-matched or pseudo-lattice-matched to the seed body 112 are formed. For example, the P-type semiconductor 222, the N-type semiconductor 224, the P-type semiconductor 226, and the N-type semiconductor 228 are sequentially formed on the seed body 112 by a selective epitaxial growth method. When a plurality of the seed bodies 112 are formed, the P-type semiconductor 222, the N-type semiconductor 224, the P-type semiconductor 226, and the N-type semiconductor 228 can be formed on each of the plurality of seed bodies 112. The epitaxial growth can be performed using the same method, conditions and materials as those in the method of producing the light emitting device 100.

Referring to FIG. 7, a cathode mesa and a gate mesa are formed by a photolithography method such as etching, and the gate electrode 232, the cathode electrode 234, and the anode electrode 236 are then formed as illustrated in FIG. 5, and the light emitting device 200 is completed. The gate electrode 232, the cathode electrode 234, and the anode electrode 236 are formed by forming a resist pattern that has apertures at positions where the gate electrode 232, the cathode electrode 234, and the anode electrode 236 are to be formed, depositing metal which is the electrode material on the mask pattern by sputtering, and then lifting off the resist.

As described above, since the light emitting device 200 has the thyristor 220 that performs the switching operation, it is possible to limit the magnitude of the driving current running through the light emitting device 200. As a result, it is possible to prevent the temperature of the light emitting device 200 from rising excessively.

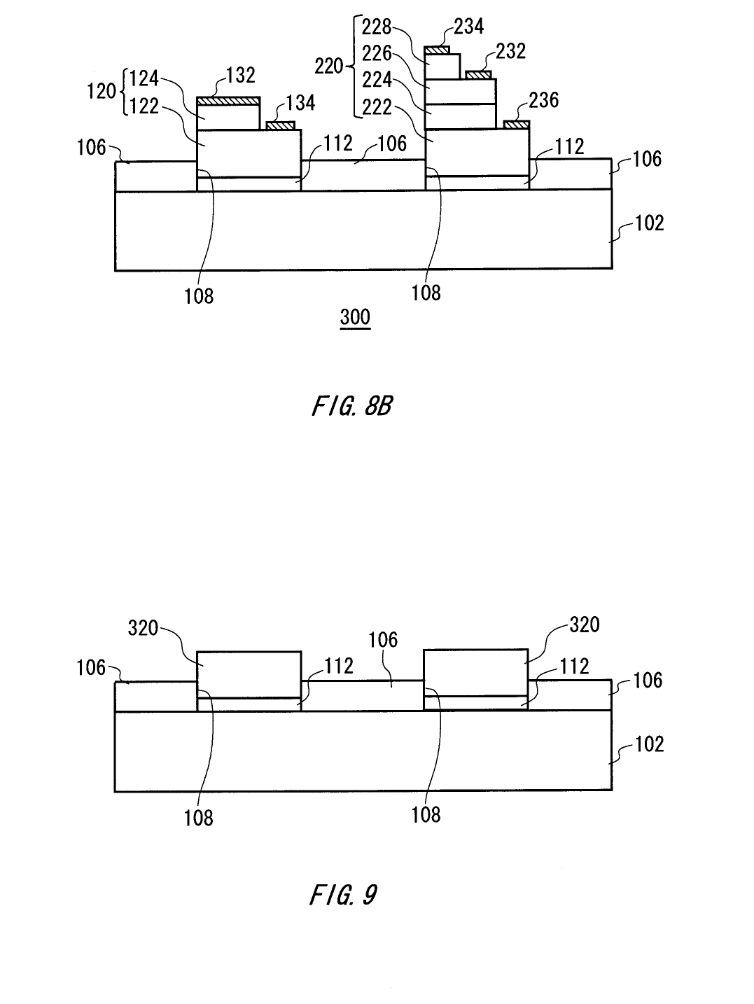

FIG. 8A shows an example of a cross section of a light emitting device 300 according to another embodiment. The light emitting device 300 includes the base wafer 102, the inhibitor 106, the seed body 112, the light emitting diode 120, the electrode 132, a resistor element 320, and an electrode 332. The base wafer 102, the inhibitor 106, the seed body 112, the light emitting diode 120, and the electrode 132 have been described above with reference to FIG. 1 and therefore explanations thereof will be hereunder omitted.

The resistor element 320 is an example of the current limiting element that limits current supplied to the light emitting diode 120. The resistor element 320 is, for example, an element included in a circuit that drives the light emitting diode 120. The resistor element 320 is formed in contact with the seed body 112. A plurality of the resistor elements 320 can be formed such that each of the resistor elements is in contact with a respective one of the seed bodies 112. The plurality of resistor elements 320 are arranged, for example, in a regular pattern. The light emitting device 300 can have other semiconductor layer between the resistor element 320 and the seed body 112.

The resistor element 320 is, for example, a Group 3-5 compound semiconductor. An example of the Group 3-5 compound semiconductor includes GaP, GaAs, GaAsP, AlGaAs, InGaP, InGaAsP, AlInGaP, GaN, InGaN, AlGaN, AlInGaN and InP. The resistor element 320 can have a multi-layered structure that includes semiconductor layers having different compositions, doping concentrations and thicknesses. The resistor element 320 is formed by, for example, a CVD, MOCVD, MBE, or ALD method.

The resistance of the resistor element 320 can be adjusted by adjusting the composition, a doping concentration, the sectional area, the thickness (length) or the like. The resistance of the resistor element 320 can be adjusted also by changing the internal structure of the resistor element 320. For example, the resistor element 320 can be formed by providing a carrier trap by adding an element that forms a deep trap level in the semiconductor. The resistance value can be adjusted by adjusting the amount of the element adding to the semiconductor.

The electrode 332 is formed in contact with the resistor element 320 and connects the resistor element 320 to an external circuit. The electrode 332 is formed of an electrically conductive material. The electrode 332 is formed of, for example, metal. A material for the electrode 332 is, for example, AuGe/Ni/Au, which are provided in the stated order from the side of the resistor element. The electrode 332 is formed by a sputtering method, a vacuum deposition method or the like.

FIG. 8B shows an example of a cross section of the light emitting device 300 according to another embodiment. The light emitting device 300 shown in FIG. 8B has the thyristor 220 that has been described with reference to FIG. 5, instead of the resistor element 320 in the light emitting element 300 illustrated in FIG. 8A. The thyristor 220 is formed by forming a multilayer structure including the P-type semiconductor 222, the N-type semiconductor 224, the P-type semiconductor 226, and the N-type semiconductor 228 sequentially stacked in the stated order from the side of the base wafer 102.

The thyristor 220 is a current limiting element that limits current to be supplied to the light emitting diode 120 by switching between a conduction state and a non-conduction state in response to a control signal input to the gate electrode 232. For example, when the cathode electrode 234 of the thyristor 220 is connected to a power source and the cathode electrode 234 of the thyristor 220 is connected to the electrode 132 of the light emitting diode 120, the thyristor 220 limits a driving current supplied via the thyristor 220 to the light emitting diode 120 according to a voltage of the control signal applied to the gate electrode 232. When the anode electrode 236 of the thyristor 220 is connected to the electrode 134 of the light emitting diode 120 and the cathode electrode 234 of the thyristor 220 is grounded, the thyristor 220 can limit a driving current output from the light emitting diode 120 according to a voltage of the control voltage applied to the gate electrode 232.

The light emitting device 300 can have two elements, which are the thyristor 220 and the resistor element 320. The resistor element 320 can limit the current supplied to the light emitting diode 120, and the thyristor 220 can control the current supplied to the light emitting diode 120.

FIGS. 9 to 11 illustrate cross sections of the light emitting device 300 during a production process. A method of producing the light emitting device 300 will be now described with reference to the accompanying drawings. The method of producing the light emitting device 300 includes forming the inhibitor 106, forming the seed body 112, and forming the resistor element 320. Heating of the seed body can be further performed between the seed body formation and the formation of the resistor element 320. In the same manner as the light emitting device 100, the semiconductor wafer shown in FIG. 3 can be obtained through the process of forming the seed body and the process of heating the seed body.

Referring to FIG. 9, when the resistor element 320 is formed, the resistor element 320 is formed in contact with the heated seed body 112. The resistor element 320 is formed by, for example, a CVD, MOCVD, MBE, or ALD method. When a plurality of the seed bodies 112 are formed, the resistor element 320 can be formed on each of the seed bodies 112.

For example, the resistor element 320 made of a Group 3-5 compound semiconductor is formed by a MOCVD method, the above-described method, conditions and source gases and so forth are adopted. The resistance value of the resistor element 320 can be adjusted by controlling the additive amount of an impurity element. Moreover, a carrier concentration in the resistor element 320 can be controlled by adjusting a molar supply ratio of a Group 5 material to a Group 3 material, and therefore it is possible to adjust the resistance value.

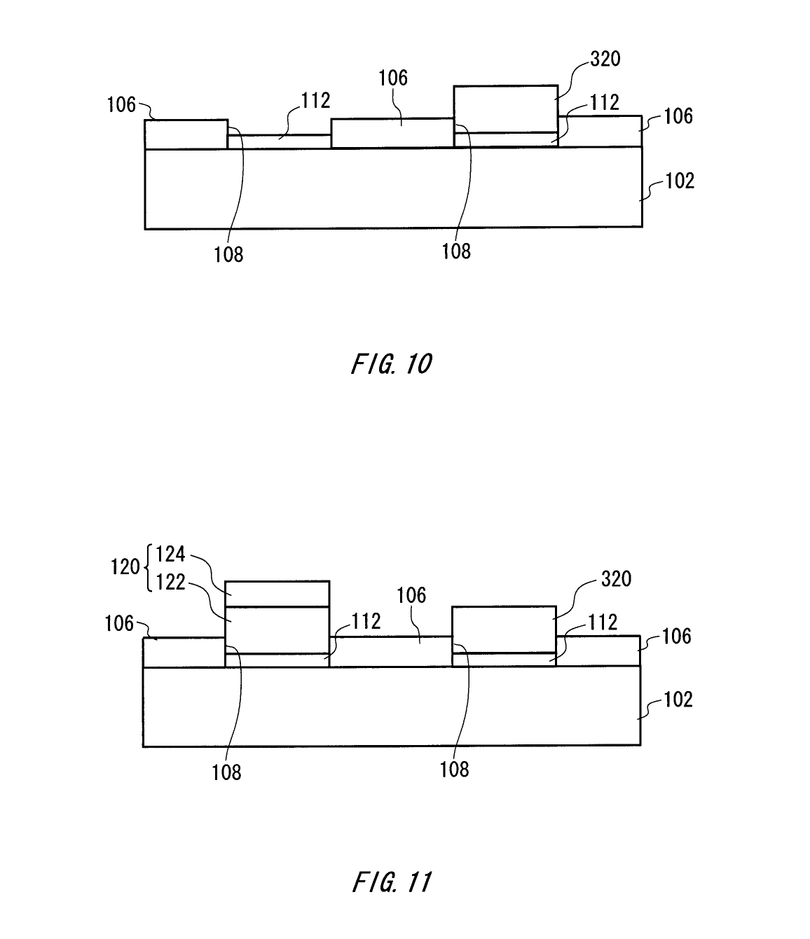

Referring to FIG. 10, the resistor element 320 at the position where the light emitting diode is to be formed is removed by a photolithography method such as etching. For example, a resist mask that covers an area other than the position is formed and then the resistor element 320 at the position can be removed by etching. Referring to FIG. 11, the resistor element 320 is removed and the light emitting diode 120 is formed in contact with the exposed seed body 112. A method of forming the light emitting diode 120 can be the same as the method of producing the light emitting device 100 described above.

Referring to FIG. 8A and FIG. 8B, the electrode 132 and the electrode 332 are subsequently formed and then the light emitting device 300 is completed. The electrode is formed by depositing a metal, which is the material for the electrode, on a mask pattern by sputtering, and then lifting off the mask.

As described above, since the light emitting device 300 has the resistor element 320 or the thyristor 220 that limits current, it is possible to limit the current to be supplied to the light emitting diode 120. Consequently, it is possible to prevent the temperature of the light emitting device 300 from rising excessively.

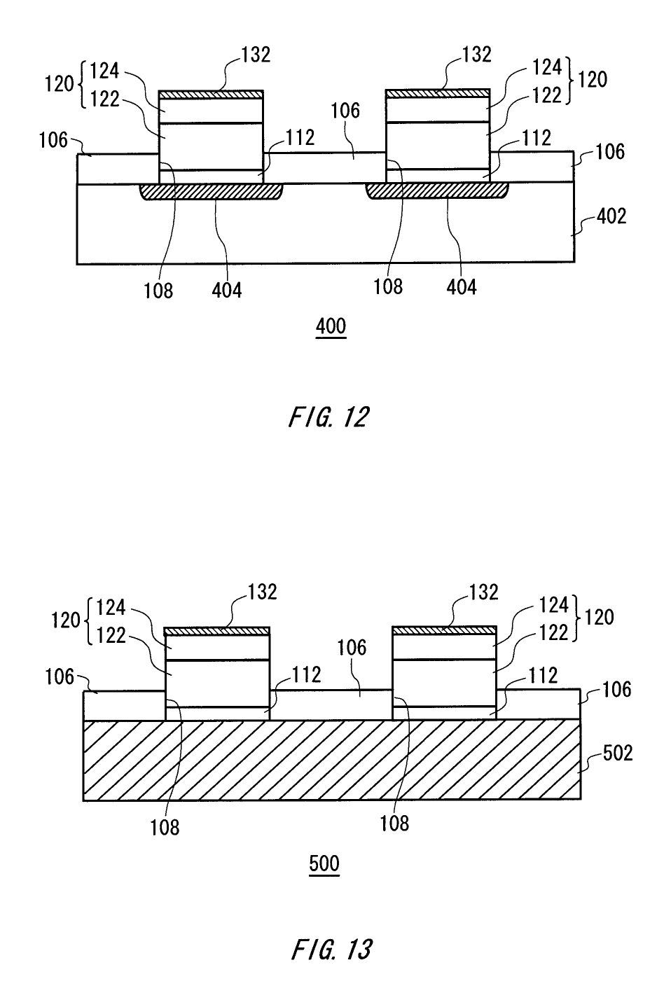

FIG. 12 shows an example of a cross section of a light emitting device 400 according to another embodiment. The light emitting device 400 includes a base wafer 402, a well region 404, the inhibitor 106, the seed body 112, the light emitting diode 120, and the electrode 132. The light emitting device 400 is different from the light emitting device 100 shown in FIG. 1 in that the base wafer 402 has the well region 404. The inhibitor 106, the seed body 112, the light emitting diode 120, and the electrode 132 have been described above with reference to FIG. 1 and therefore explanations for these elements will be hereunder omitted.

A surface of the base wafer 402 is made of silicon. The base wafer 402 has the well region 404. For example, the base wafer 102 is a high-resistance Si wafer that includes a high resistance silicon part. Whereas the base wafer 402 is a moderate-resistance or low-resistance Si wafer that contains a moderate resistance or low resistance silicon portion. The base wafer 402 is a single wafer. Here, “moderate resistance” means a resistance range of from 1 ohm·cm to several tens of ohm·cm, and “low resistance” means a resistance range of from 0.001 Ω·cm to 0.2 Ω·cm.

The well region 404 is formed in contact with the seed body 112 and electrically isolated from the silicon. For instance, the well region 404 has a different conductivity type than that of the base wafer 402, and a PN junction is formed at the interface between the well region 404 and the base wafer 402. The well region 404 and the base wafer 402 are electrically isolated each other by the PN junction. The seed body 112 is formed in contact with the well region 404. The light emitting diode 120 is electrically coupled with the well region 404 via the seed body 112. Referring to FIG. 12, a thyristor or resistor element can be provided instead of the light emitting diode 120.

FIG. 13 shows an example of a cross section of a light emitting device 500 according to another embodiment. The light emitting device 500 includes a base wafer 502, the inhibitor 106, the seed body 112, the light emitting diode 120, and the electrode 132. Only the base wafer 502 in the light emitting device 500 is different from the light emitting device 100 shown in FIG. 1. The inhibitor 106, the seed body 112, the light emitting diode 120, and the electrode 132 have been described above with reference to FIG. 1 and therefore explanations for these elements will be hereunder omitted.

A surface of the base wafer 502 is made of silicon. The base wafer 502 includes a moderate resistance or low resistance silicon portion. For example, the base wafer 502 illustrated in FIG. 13 can be a moderate-resistance or low-resistance Si wafer. The conductivity type of the base wafer 502 is same as the conductivity type of the N-type semiconductor 122 that is in contact with the seed body 112. A plurality of the light emitting diode 120 are electrically connected to each other in parallel via the seed bodies 112 and the base wafer 502.

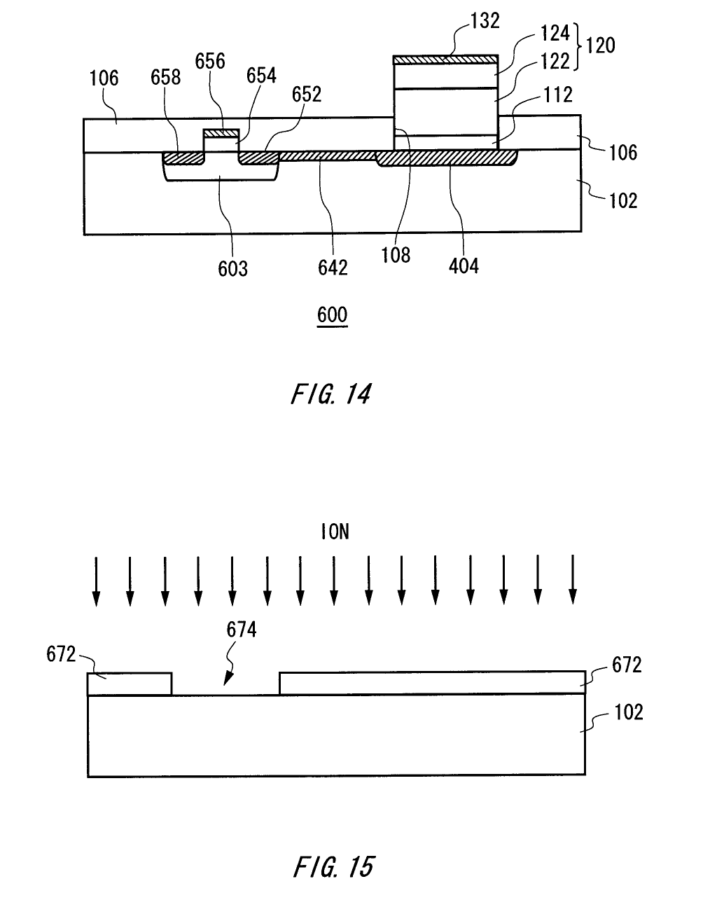

FIG. 14 shows an example of a cross section of a light emitting device 600 according to another embodiment. The light emitting device 500 includes the base wafer 102, the inhibitor 106, the seed body 112, the light emitting diode 120, a well region 603, a resistor element 642, a drain 652, a gate insulating layer 654, a gate electrode 656, and a source 658. The base wafer 102, the inhibitor 106, the seed body 112, the light emitting diode 120, and the electrode 132 have been described above with reference to FIG. 1 and therefore explanations for these elements will be hereunder omitted.

The well region 603, the drain 652, the gate insulating layer 654, the gate electrode 656, and the source 658 together form a field effect transistor (FET) which is formed in the silicon portion of the base wafer 102. The drain 652 of the FET is electrically coupled to the light emitting diode 120 via the resistor element 642, the well region 404, and the seed body 112. This FET is included in a driving circuit that drives the light emitting diode 120.

The resistor element 642 is formed in the silicon part of the base wafer 102. The resistor element 642 is included in the driving circuit that drives the light emitting diode 120. The resistance of the resistor element 642 can be adjusted by adjusting the composition, a doping concentration, the sectional area, the length or the like.

FIGS. 15 through 21 illustrate cross sections of the light emitting device 600 during a production process. A method of producing the light emitting device 600 will be now described with reference to the accompanying drawings. The method of producing the light emitting device 600 includes forming a silicon element, forming the inhibitor 106, forming the seed body 112, and forming the light emitting diode 120.

Referring to FIG. 15, during the formation of a silicon element, a mask pattern 672 is formed on the high-resistance Si base wafer 102, and the well region 603 is formed by ion-implantation. The mask pattern 672 is, for example, a photoresist mask. The mask pattern 672 is a mask made of silicon oxide, silicon nitride, or a multilayer thereof.

For example, a silicon oxide film is formed on the surface of the base wafer 102 by CVD, and then an aperture 674 is formed in the silicon oxide film at a position where the well region 603 is to be formed by a photolithography method such as etching. In this way, the mask pattern 672 can be formed. When an N-type well is formed, a Group 5 element ion such as phosphorus (P) is implanted. When a P-type well is formed, Group 3 element ion such as boron (B) is implanted. After the ion implantation, diffusion heating to heat the base wafer 102 can be performed in order to diffuse the implanted ions.

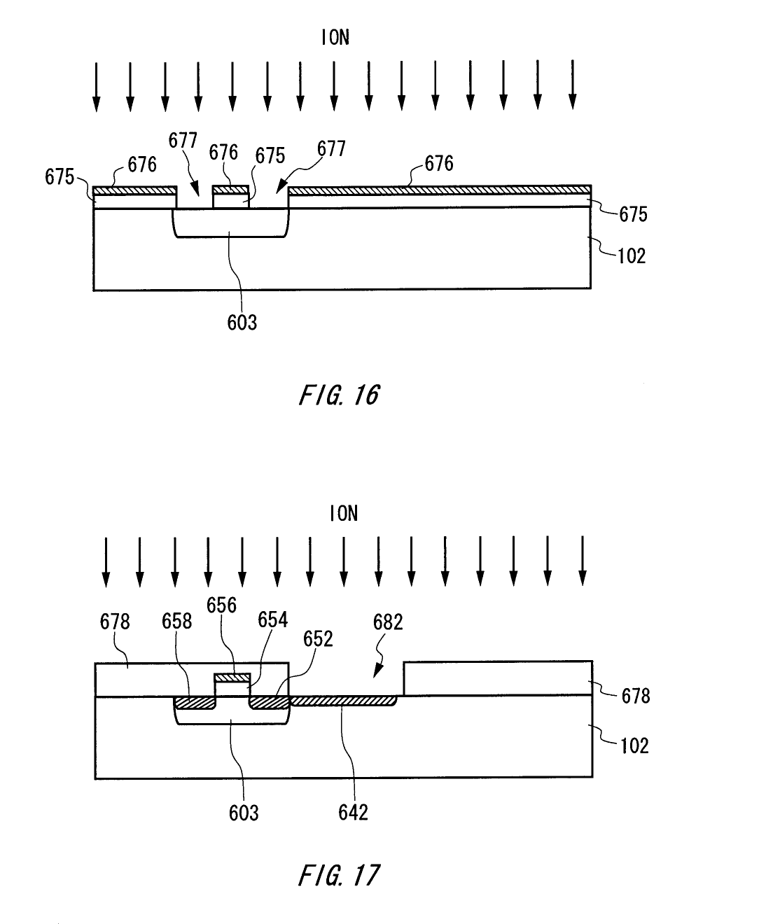

Referring now to FIG. 16, the mask pattern 672 is removed, a silicon oxide film 675 from which the gate insulating layer is formed is formed, and a polysilicon film 676 from which the gate electrode is formed is formed sequentially. The silicon oxide film 675 and the polysilicon film 676 can be formed by a CVD method. Apertures 677 are formed in the silicon oxide film 675 and the polysilicon film 676 at positions corresponding to the drain 652 and the source 658 by a photolithography method such as etching, and ion-implantation is then performed. The drain 652 and the source 658 have an opposite conductivity type to that of the well region 603. After the ion-implantation, diffusion heating can be performed.

Referring to FIG. 17, parts of the silicon oxide film 675 and the polysilicon film 676 other than the areas where the gate insulating layer 654 and the gate electrode 656 are to be formed are removed by a photolithography method such as etching. Subsequently, a mask pattern 678 used for formation of the resistor element is formed. The mask pattern 678 is, for example, a photoresist mask. The mask pattern 678 can be a mask made of silicon oxide, silicon nitride, or a multilayer thereof.

An aperture 682 is formed in a part of the mask pattern 678 corresponding to the position where the resistor element is to be formed. The mask pattern 678 can be formed in the same manner as the mask pattern 672. The resistor element 642 is formed by performing ion-implantation into the base wafer 102 through the aperture 682. The conductivity type of the resistor element 642 is the same as the conductivity type of the drain 652 and the source 658. The resistance of the resistor element 642 can be adjusted by adjusting the shape of the aperture 682 and the ion dose amount.

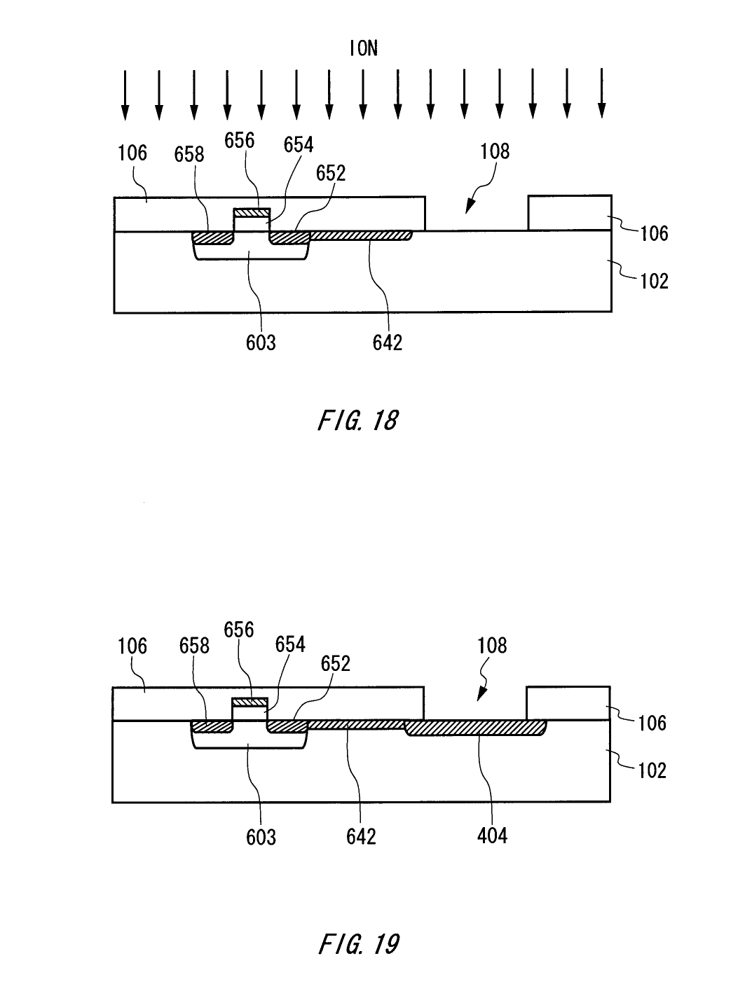

Referring to FIG. 18, during the formation of the inhibitor 106, the inhibitor 106 that covers the FET which is the silicon element formed in the silicon part of the base wafer 102 and that covers the resistor element 642 is formed, and an aperture 108 that reaches to the base wafer 102 is formed in the inhibitor 106. For example, a silicon oxide film that serves as the inhibitor 106 is formed to cover the whole surface of the base wafer 102 by for example, a CVD method, and the aperture 108 that reaches to the base wafer 102 is formed at a position where the seed body 112 is to be formed by a photolithography method such as etching. Subsequently, as illustrated in FIG. 18, the well region 404 shown in FIG. 19 is formed by performing ion implantation. The conductivity type of the well region 404 is same as the conductivity types of the drain 652 and the source 658.

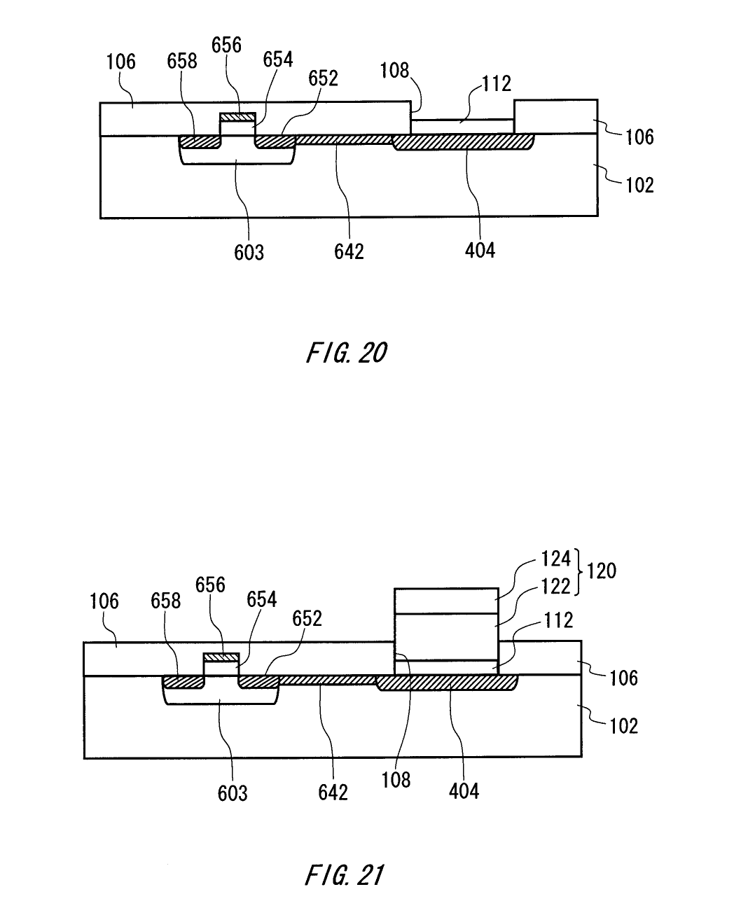

During the formation of the seed body 112, as illustrated in FIG. 20, the seed body 112 that has a composition Cx₁Si_{y1}Ge_{z1}Sn_{1-x1-y1-z1} (0≦x1<1, 0≦y1≦1, 0≦z1≦1, and 0<x1+y1+z1≦1) is formed inside the aperture 108 by a selective epitaxial growth method. The epitaxial growth method includes CVD, MOCVD, MBE and ALD methods. For example, a SiGe crystal can be formed as the seed body 112 by a CVD method. On the surface of the inhibitor 106, epitaxial growth of the seed body 112 is inhibited and therefore the seed body 112 is selectively grown epitaxially inside the aperture 108. The seed body 112 can be heated.

During the formation of the light emitting diode 120, as illustrated in FIG. 21, the N-type semiconductor 122 and the P-type semiconductor 124 that are lattice-matched or pseudo-lattice-matched to the corresponding seed body 112 are formed so as to be in contact with the corresponding seed body 112. The electrode 132 is then formed as shown in FIG. 14. The method for the formation of the electrode 132 is similar to the light emitting device 100 and therefore its description will be omitted.

The above description about the method of producing the light emitting device 600 does not limit the order of processes to be performed in the method. For example, a silicon element can be formed after the completion of the formation of the inhibitor 106, the formation of the seed body 112 and the formation of the light emitting diode 120.

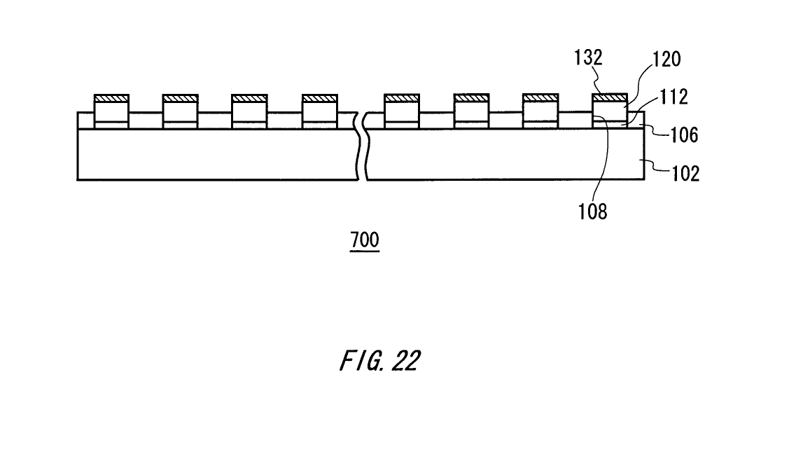

FIG. 22 illustrates an example of a cross section of a light emitting device 700. The light emitting device 700 include the base wafer 102, the inhibitor 106, the seed body 112, the light emitting diode 120, and the electrode 132. The light emitting device 700 includes the same components as the light emitting device 100, however light emitting device 700 more light emitting diodes 120 than those in the light emitting device 100 and has a following difference.

A plurality of the apertures 108 are arranged regularly in the inhibitor 106. Some of the plurality of apertures 108 have the seed bodies 112 provided therein. The light emitting diode 120 can be formed on the seed body 112. The plurality of light emitting diodes 120 can be arranged regularly. FIG. 22 illustrates the plurality of light emitting diodes 120 that are arranged in line in the horizontal direction. For example, by arranging the light emitting diodes 120 in this way, an LED array can be formed. Such LED arrays are used for, for instance, printer heads.

Here, “arranged regularly” means that elements are arranged in accordance with some rules. An example of such rule includes arranging elements in a x-axis direction in one line at regular intervals, arranging elements in a y-axis direction in one line at regular intervals, arranging elements in a lattice pattern in the x-axis direction and the y-axis direction at regular intervals, and arranging elements in a hound's-tooth pattern. For example, the plurality of apertures can be arranged in a regular lattice pattern, and cells can be provided in some of the plurality of apertures. These cells can be arranged such that two adjacent lines have different arrangements to form a regular hound's-tooth pattern. At least some or all of the cells can serve as light emitting cells. The arrangement pattern of the apertures can be same or different from the arrangement pattern of the cells.

Each of the light emitting diodes 120 has a driving circuit to drive the corresponding light emitting diode. The driving circuit includes, for example, the resistor element 320 illustrated in FIG. 8A or the thyristor 220 illustrated in FIG. 8B. The driving circuit can include the silicon element illustrated in FIG. 14. For instance, the driving circuit includes a transistor, a resistor element and so forth formed in silicon of the base wafer 102.

Although the light emitting device 700 includes the plurality of light emitting diodes 120 in the example illustrated in FIG. 22, the light emitting device 700 can include thyristors instead. Moreover, the seed body 112 can be respectively formed in some of the plurality of apertures 108 and the resistor element 320 shown in FIG. 8A can also be formed thereon. The plurality of resistor elements 320 can be arranged regularly.

1. A light emitting device comprising:
a base wafer that contains silicon;
a plurality of seed bodies provided in contact with the base wafer; and
a plurality of Group 3-5 compound semiconductors each lattice-matching or pseudo-lattice-matching corresponding seed bodies, wherein
a light emitting element that emits light in response to current supplied thereto is formed in at least one of the plurality of the Group 3-5 compound semiconductors, and
a current limiting element that limits the current supplied to the light emitting element is formed in at least one of the plurality of the Group 3-5 compound semiconductors other than the Group 3-5 compound semiconductor in which the light emitting element is formed.

2. The light emitting device according to claim 1, further comprising:
an inhibitor that inhibits crystal growth and in which a plurality of apertures exposing at least a part of the base wafer are provided, the inhibitor being formed directly or indirectly on the base wafer, wherein
the plurality of the seed bodies are provided in the plurality of the apertures.

3. The light emitting device according to claim 1, wherein,
the plurality of the seed bodies have a composition Cₓ₁Si_{y1}Ge_{z1}Sn_{1-x1-y1-z1} (0≦x1<1, 0≦y1≦1, 0≦z1≦1, and 0<x1+y1+z1≦1).

4. The light emitting device according to claim 3, further comprising:
an interface region provided inside the base wafer in contact with an interface between the base wafer and the seed body, the interface region having a composition Cₓ₂Si_{y2}Ge_{z2}Sn_{1-x2-y2-z2} (0≦x2<1, 0<y2≦1, 0≦z2≦1, and 0<x2+y2+z2≦1), wherein
x1 for the seed body and x2 for the region satisfy the relation x1>x2,
y1 for the seed body and y2 for the region satisfy the relation y1<y2,
z1 for the seed body and z2 for the region satisfy the relation z1>z2, and
1−x1−y1−z1 for the seed body and 1−x2−y2−z2 for the region satisfy the relation 1−x1−y1−z1>1−x2−y2−z2.

5. The light emitting device according to claim 1, wherein,
the base wafer has a well region that is in contact with the plurality of the seed bodies, and
the light emitting element is electrically coupled to the current limiting element via the plurality of the seed bodies and the well region.

6. The light emitting device according to claim 1, wherein,
the current limiting element is a resistor element that limits current to be supplied to the light emitting element.

7. The light emitting device according to claim 6, wherein,
the resistor element includes a carrier trap that traps a carrier.

8. The light emitting device according to claim 1, wherein,
the current limiting element is a thyristor that switches current to be supplied to the light emitting element.

9. The light emitting device according to claim 8, wherein,
the thyristor includes a multilayered structure in which a P-type semiconductor, an N-type semiconductor, a P-type semiconductor, and an N-type semiconductor are layered in the stated order.

10. The light emitting device according to claim 1, wherein,
the silicon has the same conductivity type as the conductivity type of the plurality of the Group 3-5 compound semiconductors that are in contact with the plurality of the seed bodies.

11. The light emitting device according to claim 1, further comprising:
a silicon element formed in a region of the base wafer, the region containing the silicon, wherein
the silicon element supplies current to the light emitting element.

12. The light emitting device according to claim 2, wherein,
the plurality of the apertures are arranged at regular intervals in the inhibitor.

13. A method of producing a light emitting device, comprising:
forming a plurality of seed bodies in contact with a base wafer whose surface is made of silicon;
forming a plurality of Group 3-5 compound semiconductors each lattice-matching or pseudo-lattice-matching a corresponding seed body by crystal growth;
forming, in at least one of the plurality of the Group 3-5 compound semiconductors, a light emitting element that emits light in response to current to be supplied thereto; and
forming, in at least one of the plurality of the Group 3-5 compound semiconductors other than the Group 3-5 compound semiconductor in which the light emitting element is formed, a current limiting element that limits current to be supplied to the light emitting element.

14. The method according to claim 13 of producing a light emitting device, further comprising:
heating the plurality of the seed bodies after forming the plurality of the seed bodies and before forming the plurality of the Group 3-5 compound semiconductors by crystal growth.

15. The method according to claim 13 of producing a light emitting device, further comprising:
forming, directly or indirectly on the base wafer, an inhibitor that inhibits crystal growth and that has a plurality of apertures in which at least a part of the base wafer is exposed, wherein
in forming the plurality of the seed bodies, the seed bodies are provided in the apertures.

16. A semiconductor wafer comprising:
a base wafer that contains silicon;
a plurality of seed bodies provided in contact with the base wafer; and
a plurality of Group 3-5 compound semiconductors each lattice-matching or pseudo-lattice-matching a corresponding seed body, wherein
at least one of the plurality of the Group 3-5 compound semiconductors is a semiconductor that can serve as a light emitting element that emits light in response to current to be supplied thereto, and
at least one of the plurality of the Group 3-5 compound semiconductors other than the semiconductor that can serve as the light emitting element includes a multilayered structure in which a P-type semiconductor, an N-type semiconductor, a P-type semiconductor, and an N-type semiconductor are layered in the stated order.

17. A method of producing a semiconductor wafer, comprising:
forming a plurality of seed bodies in contact with a base wafer whose surface is made of silicon; and
growing a plurality of Group 3-5 compound semiconductors that are lattice-matched or pseudo-lattice-matched to corresponding seed bodies, wherein
growing the plurality of Group 3-5 compound semiconductors includes:
forming a semiconductor from which a light emitting element emitting light according to current supplied thereto can be formed as at least one of the plurality of Group 3-5 compound semiconductors, and
forming a multilayered structure in which a P-type semiconductor, an N-type semiconductor, a P-type semiconductor, and an N-type semiconductor are layered in the stated order as at least one of the plurality of the Group 3-5 compound semiconductors other than the semiconductor that can serve as the light emitting element.
